(19) United States
(12) Patent Application Publication
(10) Pub. No.: US 2026/0299063 A1
(43) Pub. Date: Oct. 1, 2026

(54) Acquisition of Magnetic Resonance Data

(71) Applicant: Siemens Healthineers AG, Forchheim (DE)

(72) Inventor: Alto Stemmer, Uttenreuth (DE)

(73) Assignee: Siemens Healthineers AG, Forchheim (DE)

(21) Appl. No.: 19/632,695

(22) Filed: Mar. 30, 2026

(30) Foreign Application Priority Data
Mar. 31, 2025 (DE) 10 2025 112 403.5

(51) Int. Cl. G01R 33/36; G01R 33/385; G01R 33/483

(52) U.S. Cl. CPC G01R 33/3664; G01R 33/3607; G01R 33/3852; G01R 33/4835

(57) ABSTRACT

A method according to the disclosure for the acquisition of measurement data of an examination subject using a magnetic resonance system includes the steps: applying an asymmetric RF excitation pulse, after the asymmetric RF excitation pulse has been applied, applying a sequence of at least two RF refocusing pulses, with a first time interval from one another in each case, in order to generate spin echo signals, switching gradients for spatial encoding of generated spin echo signals, and reading out generated spin echo signals after each applied RF refocusing pulse as measurement data in the k-space according to the respective spatial encoding, from which image data can be reconstructed, wherein a time interval between the isodelay time of the asymmetric RF excitation pulse and the temporal center of the first RF refocusing pulse following the RF excitation pulse is equal to half the first time interval.

### TECHNICAL FIELD

The disclosure relates to an improved acquisition of magnetic resonance data, in [symbol] ular by means of a turbo spin echo technique.

### BACKGROUND

Magnetic resonance technology (in the following, the abbreviation MR stands for [symbol] etic resonance) is a well-known imaging modality by means of which images of the [symbol] of an examination subject can be generated. In simple terms, the examination subject is [symbol] oned for this purpose in a magnetic resonance device in a comparatively strong, static, [symbol] geneous basic magnetic field, also known as the B0 field, at field strengths of 0.2 Tesla [symbol] Tesla and more, such that its nuclear spins align themselves along the basic magnetic [symbol] In order to trigger nuclear spin resonances that are measurable as signals, [symbol] frequency excitation pulses (RF pulses) are transmitted into the examination subject, the [symbol] red nuclear spin resonances are measured as data known as k-space data by means of [symbol] configured for receiving signals, and MR images are reconstructed, or spectroscopic data is determined on the basis thereof. The alternating magnetic field generated by the excitation pulses broadcast by means of the at least one transmit coil is also referred to as the B1 field. For spatially encoding the measurement data, rapidly switched magnetic gradient fields, called gradients for short, are superimposed on the basic magnetic field. A scheme used that describes a temporal sequence of RF pulses to be transmitted and gradients to be switched is referred to as a pulse sequence (scheme), or also as a sequence for short. The recorded measurement data is digitized and stored as complex numeric values in a k-space matrix. An associated MR image can be reconstructed from the k-space matrix populated with values, e.g., by means of a multidimensional Fourier transform.

In this case, there are essentially two ways of generating echo signals following an excitation of the nuclear spins. On the one hand, the excited nuclear spins can be manipulated by switching dephasing and rephasing gradients in such a way that the signal decays more rapidly than is due to the T2* decay inherent in the measured tissue, but after a certain time, the echo time (TE), following the isodelay time of the RF excitation pulse used there is formed what is termed a gradient echo (GRE) that is to be measured. Sequences of said type are generally referred to as GRE sequences.

On the other hand, a sequence known as a spin echo (SE) can also be generated by application of at least one RF refocusing pulse after the application of an RF excitation pulse after a time, again referred to as the echo time, following the isodelay time of the RF excitation pulse, which spin echo SE is measured and its amplitude, though, is reduced in accordance with the T2 decay inherent in the measured tissue. Sequences of said type are generally referred to as SE sequences. In each case, the excitation and the measurement of the generated echo signals in each sequence are repeated as necessary (e.g., with switching of different gradients for spatial encoding purposes) until the desired number of echo signals has been measured and stored at the desired density in the k-space in order to enable the examination subject to be imaged.

In this context, the isodelay time of an RF excitation pulse is defined as follows: After an RF excitation pulse has been applied while switching a (slice selection) gradient for selecting the slice, and consequently a selective RF excitation pulse, a phase dispersion of the generated transverse magnetization is effected in the direction of the slice selection gradient. With a certain class of RF pulses (known as linear-phase pulses), the phase dispersion can be completely turned back with the aid of a slice rephasing gradient, which is generally switched following the slice selection gradient and has a reverse polarity to the latter. In this case, the isodelay time of the RF excitation pulse determines the moment of the slice rephasing gradient since the moment of the slice selection gradient from the isodelay time of the RF excitation pulse to the end of the slice selection gradient is equal to the negative moment of the slice rephasing gradient. With a symmetrical RF excitation pulse, its isodelay time lies in the center of the RF excitation pulse.

Among the SE sequences, in particular the TSE sequences (TSE: Turbo Spin Echo), which are also known by the names FSE (Fast Spin Echo) or RARE (Rapid Acquisition with Refocused Echoes) sequences, are widely established in clinical application. The advantage of the TSE sequences compared to the “simple” SE sequence is that after an RF excitation pulse, a plurality of RF refocusing pulses are switched, and that in consequence a plurality of spin echo signals (one after every RF refocusing pulse) are also generated which can be encoded individually such that after an RF excitation pulse, e.g., a plurality of k-space lines can be sampled. This results in faster data acquisition.

The time interval between consecutive spin echo signals, referred to in the following as the echo spacing, in an echo train of spin echo signals after a common RF excitation pulse is constant and a characteristic variable of a TSE sequence.

With conventional approaches, images of the interior of an examination subject are acquired slice by slice. In such slice-by-slice processes, also referred to as two-dimensional (2D) acquisition techniques, a relatively thin slice, typically between 1 and 5 mm, is excited selectively in each case. Such a selective excitation is achieved by applying a gradient in the slice selection direction in coordination with a transmitted exciting RF excitation pulse. What is achieved by means of such a pulse arrangement (consisting of the exciting RF excitation pulse and the associated gradient) is that the RF excitation pulse acts only selectively on the region determined by the gradient and the RF pulse in the examination subject. In most cases, this slice selection direction runs parallel to an axis known as the z-axis, i.e., the longitudinal axis of the magnetic resonance system, or also parallel to the longitudinal axis of a patient lying in the magnetic resonance system. A spatial encoding within a slice is then performed on the one hand by a phase encoding in a direction perpendicular to the slice selection direction (generally referred to as the y-direction) and by a readout encoding in the second direction perpendicular to the slice selection direction (generally referred to as the x-direction). In this way a two-dimensional frequency space, known as the k-space, can be filled by entering the measured measurement data as raw data at the corresponding k-space points. An image of the slice can be generated therefrom by means of a two-dimensional Fourier transform.

It is also possible to excite larger three-dimensional volumes and measure them in a 3D method. In this case, instead of a thin image slice (generally referred to simply as a “slice”), a relatively thick slice (generally referred to as a “slab”) is excited in an excitation process. However, these slabs, mostly more than 10 mm thick, must be measured once again, spatially resolved in the slice selection direction during the acquisition of the raw data. This is usually accomplished by means of a second phase encoding, i.e., with this method the measurement is conducted phase-encoded in two directions and readout-encoded in one direction in order in this way to fill a three-dimensional k-space with raw data and generate a three-dimensional image volume therefrom by means of a 3D Fourier transform.

A method in which raw data is acquired in this way from a single cohesive 3D volume is also referred to as a single-slab method. The cohesive 3D volume permits the use of short non-selective RF refocusing pulses. Such short non-selective RF refocusing pulses allow a short echo spacing of the TSE sequence and consequently a large number of echoes to be read out in an echo train before the excited signal has decayed. In addition, the duration of the usable echo train can be extended by means of a succession of flip angles of the RF refocusing pulse optimized for the desired contrast. Both measures together permit the length of the echo train to be extended in such a way that 3D imaging is possible in clinically acceptable times and permits high-resolution three-dimensional (3D) images to be generated in a short time.

This sequence class is also referred to in the literature inter alia as a single-slab 3D FSE sequence. Other acronyms in this sequence class include SPACE (“Sampling Perfection with Application optimized Contrasts using different flip angle Evolutions”), CUBE, or VISTA. The article by Mugler III titled “Optimized Three-Dimensional Fast-Spin-Echo MRI”, J. Magn. Res. Imag. 39: pp. 745-767, 2014 offers a technical overview in relation to this sequence technique, which is referred to in the following mostly as SPACE for short.

It is possible, for example in certain orientations and regions of a body of a patient as examination subject, such as, for instance, in a sagittal imaging of the head, to use non-selective short RF pulses also for the excitation of the spins within a SPACE sequence. The use of such non-selective RF excitation pulses permits a short echo spacing (e.g., of about less than or equal to 4 milliseconds) while simultaneously meeting the so-called “Carr Purcell Meiboom Gil” (CPMG) conditions. The CPMG conditions formulate design guidelines for a TSE sequence that ensure that echo signals of the generated magnetization that follow different signal paths constructively overlap one another. One CPMG condition requires the time interval between two consecutive RF refocusing pulses to be equal to the echo spacing, and the time interval between RF excitation pulse and first RF refocusing pulse to be equal to half the echo spacing.

The CPMG conditions can generally be formulated as follows:

Condition 1: The RF refocusing pulses must be positioned by 90° out of phase in comparison with the RF excitation pulse and uniformly in the sequence with equal spacing between two consecutive refocusing pulses. The spacing must amount to twice the time interval between the RF excitation pulse and the first RF refocusing pulse.

Condition 2: The phases accumulated by a spin isochromat, i.e., spins of a same spin species, between two consecutive RF refocusing pulses must be equal.

When conditions 1 and 2 are both met, primary and stimulated echoes occur only at the temporal center point between two consecutive RF refocusing pulses and have the same phase.

However, in most orientations and regions of a patient's body as an examination subject, a spatially selective variant of the SPACE sequence is necessary. This spatially selective variant requires the use of longer selective RF pulses either for the excitation or for the refocusing of at least one first echo signal after an RF excitation pulse.

In known SPACE techniques, the use of selective RF pulses for the excitation or the refocusing leads either to the echo spacing being lengthened, which reduces the efficiency and image quality of the sequence, or to a violation of the CPMG conditions, and consequently, among other things, to signal losses in the case of variations of the B1 field in the imaging volume.

FIG. 1 is a typical schematic sequence diagram for a known selective SPACE sequence, e.g., from the article by Mugler III et al. titled “Efficient Spatially-Selective Single-Slab 3D Turbo-Spin-Echo Imaging”, Proc. Intl. Soc. Mag. Reson. Med. 11, p. 695, 2004, wherein RF pulses to be applied are shown in the top line RF, gradients to be switched in the slice-encoding direction are shown in the second line GS, gradients to be switched in the readout direction are shown in the third line GR, and acquisition time windows A, within which raw data is acquired as measurement data, are shown in their temporal sequence in the bottom line ADC.

In this case, the time interval ES1 between the (symmetric) selective RF excitation pulse RF1′ and the first spin echo signal E1, refocused by means of a first RF refocusing pulse RF2, the first echo spacing ES1, is chosen longer than the echo spacing ES2 in each case between consecutive spin echo signals E1, E2, E3, E4. The first spin echo signal E1 is therefore refocused repeatedly by a succession of non-selective RF refocusing pulses RF3 that are applied in a time interval corresponding to the second echo spacing ES2. The time interval between the first spin echo signal E1 and the RF refocusing pulse RF3 applied thereafter amounts to

$$\frac{ES 2}{2}$$

so that the second spin echo signal E2 is formed in the temporal center between the two RF refocusing pulses RF3 following the first spin echo signal E1. Stimulated echoes associated with the first RF refocusing pulse RF2 would be formed at a different point in time. A stimulated echo generated by the RF excitation pulse RF1′, the first applied RF refocusing pulse RF2 and the following applied RF refocusing pulse RF3 would be produced, for example.

$$\frac{ES 1}{2} + \frac{ES 2}{2}$$

after the first spin echo signal E1, and therefore later than the second spin echo signal E2 generated by the cited three RF pulses RF1′, RF2, RF3. In order to avoid the formation of stimulated echoes in which the first RF refocusing pulse RF2 is involved, the flip angle of the first RF refocusing pulse RF2 can be set equal to 180°. However, due to a technically unavoidable variation of the B1 field in the acquired volume, stimulated echoes cannot be completely avoided by this means. These can however be dephased by so-called crusher gradients which are switched before and after the first RF refocusing pulse RF2, e.g., in the slice selection direction GS, since the magnetization that would later form the stimulated echo is situated only between the RF excitation pulse RF1′ and the first RF refocusing pulse RF2 in the transverse plane, and consequently is dephased by a crusher gradient switched before the RF refocusing pulse RF2. The magnetization that later forms the first spin echo signal E1, for example, is, on the other hand, located before and after the first RF refocusing pulse RF2 in the transverse plane such that it is dephased by a crusher gradient switched before the RF refocusing pulse RF2 and rephased by the second crusher gradient switched after the RF refocusing pulse RF2.

A disadvantage of such a method using crusher gradients is that the signal dephased with first crusher gradients is lost for the imaging. The extended first echo spacing ES1 therefore leads here to an unwanted sensitization toward variations of the B1 field.

Furthermore, due to what are called J coupling effects, the extended first echo spacing ES1 affects the fat/water contrast that can be achieved by means of the acquisition. More details in this regard are described, for example, in the article by Stables et al. titled “Analysis of J Coupling-Induced Fat Suppression in DIET Imaging”, J. Magn. Reson. 136: pp. 143-151, 1999. As a result, fat appears less bright than in a CPMG TSE sequence. This can be disadvantageous, in particular for the visualization of bone tissue.

Further, the extended first echo spacing ES1 also limits the minimum echo time TE of the sequence downward.

A variant of a method described with reference to FIG. 1 with extended first echo spacing ES1 which replaces the selective RF excitation pulse RF1′ (and the first RF refocusing pulse RF2) from FIG. 1 by a composite RF pulse, consisting of an adiabatic non-selective RF excitation pulse (AHP pulse, “adiabatic half-passage”) and a pair of selective adiabatic RF pulses (AFP pulses, “adiabatic full-passage”) is known for example from the article by Park et al. titled “Reduction of B1 Sensitivity in Selective Single-Slab 3D Turbo Spin Echo Imaging with Very Long Echo Trains”, Magn. Reson. Med. 62: pp. 1060-1066, 2009. Furthermore, the strategy of the unequal echo spacings ES1 and ES2 was adapted in order to be able to use the long adiabatic pulses of the composite RF pulse efficiently in conjunction with the following short non-selective RF refocusing pulses RF3.

Adiabatic pulses are a special class of RF pulses that, even in the presence of a spatially non-uniform B1 field, can excite, refocus, and/or uniformly invert magnetization vectors. For conventional RF pulses, the relation

$$α = γ {\int }_{0}^{T} {B}_{1} ( t ) dt$$

applies between the flip angle α and the B₁ field amplitude. Accordingly, the flip angle varies with the B₁ field. As a result of the special modulation of the amplitude and frequency (or phase), adiabatic RF pulse spins that experience different B1 fields can excite, refocus, or invert using the same flip angle if the amplitude of the B1 modulation envelope exceeds a threshold value, known as the adiabatic limit.

By using the composite adiabatic RF pulse, the above-criticized B1 sensitivity is successfully reduced by means of the method described in the cited article by Park. However, this method is in turn suitable only for measurements using T2 weighting since the first spin echo signal can only be read out after the doubling of the first echo spacing, 2×ES1, following the RF excitation pulse RF1′ (see FIG. 3 in the cited article by Park et al.) and in the process the first echo spacing ES1 lies in the order of 13 milliseconds due to the relatively long duration of the adiabatic RF pulses used. Furthermore, as in the case of the method described with reference to FIG. 1, the fat/water contrast is also changed compared with a CPMG TSE. In addition, adiabatic RF pulses are generally associated with a relatively high SAR exposure (SAR: Specific Absorption Rate).

A further variant of a method described with reference to FIG. 1 is known from the article by Cai et al. titled “3D Turbo-Spin-Echo with VERSE Excitation Improves SNR for Brachial Plexus Magnetic Resonance Neurography”, Proc. Intl. Soc. Mag. Reson. Med, p. 491, 2024. This manages to get by without extending the first echo spacing ES1 and replaces the long selective RF excitation pulse RF1′ shown in FIG. 1 by a VERSE RF pulse (VERSE: “variable-rate selective excitation”). The VERSE technique permits the B1 amplitude in the temporal center of the RF pulse to be reduced by a simultaneous lowering of the amplitude of a (slice selection) gradient for slice selection switched at the same time as the VERSE RF pulse. This enables VERSE RF pulses to be shortened without exceeding a maximum B1 amplitude of a power amplifier used to generate the RF pulses. As a result of the cited variation of the amplitude of the slice selection gradient, however, there is an increase in off-resonance sensitivity, i.e., in particular a sensitivity toward inhomogeneities of the basic magnetic field B0, of the sequence. This is a disadvantage, in particular when signal from fat tissue is not suppressed in the image. Furthermore, the VERSE RF pulse is also longer than a non-selective RF excitation pulse, such that in general the echo spacing is extended compared with a non-selective SPACE variant with otherwise identical imaging parameters, thereby reducing efficiency and image quality.

There is therefore a continuing requirement to provide a further improvement in TSE sequences in order to avoid or at least reduce the cited disadvantages, such as, e.g., violation of the CPMG condition, B1 sensitivity, B0 sensitivity, changed fat/water contrast and/or high SAR exposure, and at the same time to enable the shortest possible (effective) echo times which in particular can avoid T2 blurring, and/or to improve an achieved slice profile (also known as an excitation profile).

### SUMMARY

The object underlying the aspects of this disclosure is to enable an improved determination of coil sensitivity data which in particular reduces a contamination of the reference data due to interference effects.

The object is achieved by means of a method for acquiring measurement data of an examination subject according to claim 1, a magnetic resonance system according to claim 13, a computer program according to claim 14, and an electronically readable data medium according to claim 15.

A method according to the disclosure for acquiring measurement data of an examination subject by means of a magnetic resonance system comprises the steps:
applying an asymmetric RF excitation pulse,
after the asymmetric RF excitation pulse has been applied, applying a sequence of at least two RF refocusing pulses, with a first time interval from one another in each case, in order to generate spin echo signals,
switching gradients for spatial encoding of generated spin echo signals,
reading out generated spin echo signals after each applied RF refocusing pulse as measurement data in the k-space according to the respective spatial encoding, from which image data can be reconstructed,
wherein a time interval between the isodelay time of the asymmetric RF excitation pulse and the temporal center of the first RF refocusing pulse following the RF excitation pulse is equal to half the first time interval.

An inventive use of asymmetric RF excitation pulses whose isodelay time in particular lies closer to the end of the asymmetric RF excitation pulse than to its beginning permits an in particular selective excitation without performing an above-described extension, necessary in the prior art, of the (first) echo time (compared to an otherwise identical but non-selective excitation), and consequently not changing a fat/water contrast, without violating the CPMG conditions. The thus achieved advantage of enabling particularly short echo times can, in particular for all 2D or 3D TSE sequences in which gradients to be switched between the applied RF excitation pulse and the first applied RF refocusing pulse limit the echo spacing downward, lead to a great improvement in image quality, in which case potentially achievable echo spacings even with a spatially selective excitation can be chosen even shorter than with a non-selective excitation.

Furthermore, a SAR exposure as well as sensitivities toward B1 and/or B0 inhomogeneities can be reduced by means of the asymmetric RF excitation pulse.

A magnetic resonance system according to the disclosure comprises a magnet unit, a gradient unit, a radiofrequency unit, and a control device designed to perform a method according to the disclosure and having an asymmetry unit.

A computer program according to the disclosure implements a method according to the disclosure on a control device when it is executed on the control device. For example, the computer program comprises commands which, when the program is executed by a control device, e.g., a control device of a magnetic resonance system, cause said control device to perform a method according to the disclosure. The control device may be designed in the form of a computer.

In this case, the computer program may also be present in the form of a computer program product which can be loaded directly into a memory of a control device and has program code means in order to perform a method according to the disclosure when the computer program product is executed in a computing unit of a computing system of the control device.

A computer-readable storage medium according to the disclosure comprises commands which, when executed by a control device, e.g., a control device of a magnetic resonance system, cause said control device to perform a method according to the disclosure.

The computer-readable storage medium may be implemented as an electronically readable data medium on which electronically readable control information is stored which comprises at least one computer program according to the disclosure and is designed in such a way that it performs a method according to the disclosure when the data medium is used in a control device of a magnetic resonance system.

The advantages and statements cited in relation to the method also apply analogously to the magnetic resonance system, the computer program product, and the electronically readable data medium.

### BRIEF DESCRIPTION OF THE DRAWINGS

Further advantages and details of the present disclosure will become apparent from the exemplary aspects described in the following, as well as with reference to the drawings. The examples presented do not imply any limitation of the disclosure. In the drawings:

FIG. 1 shows a schematic sequence diagram of a known selective SPACE technique,

FIG. 2 shows a schematic flowchart of a method according to the disclosure for acquiring measurement data,

FIGS. 3-5 show schematic sequence diagrams of proposed variants for acquiring measurement data, and

FIG. 6 shows a schematically represented magnetic resonance system according to the disclosure.

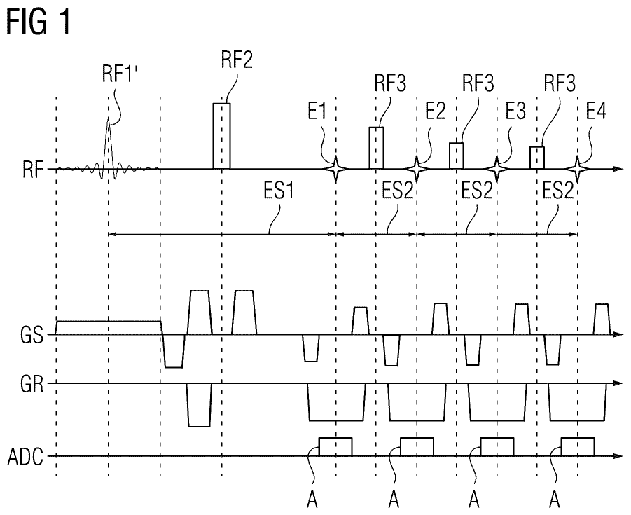

### DETAILED DESCRIPTION

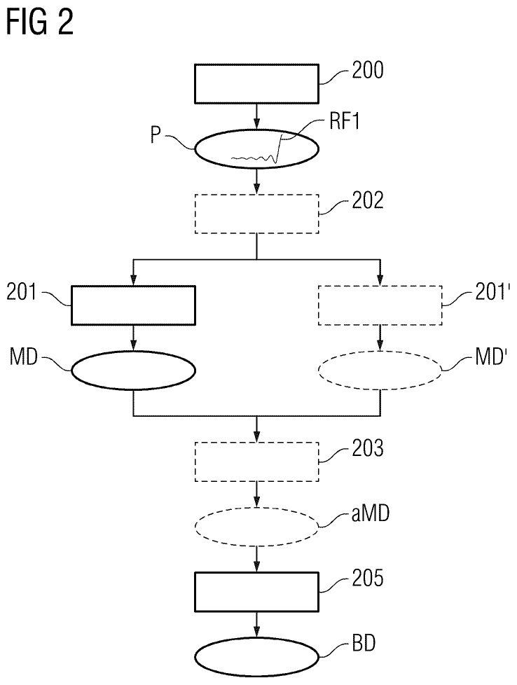

FIG. 2 is a schematic flowchart of a method according to the disclosure for acquiring measurement data of an examination subject U by means of a magnetic resonance system 1.

Here, parameters P of a sequence to be performed in order to acquire measurement data are loaded, which in particular comprise an asymmetric RF excitation pulse RF1 (block 200). The sequence to be performed can be in particular a form of a TSE sequence in which a train of spin echo signals is generated by applying a sequence of at least two RF refocusing pulses, which can be in particular (spatially) non-selective RF refocusing pulses, e.g., so-called RF hard pulses, with a first time interval ES2 from one another in each case after the application of the asymmetric RF excitation pulse and can be read out as measurement data, wherein a spatial encoding of the measurement data is performed in a per se known manner by switching of gradients.

The sequence to be performed is executed using the loaded parameters P (block 201) in order to acquire measurement data MD from which image data BD can be reconstructed (block 205).

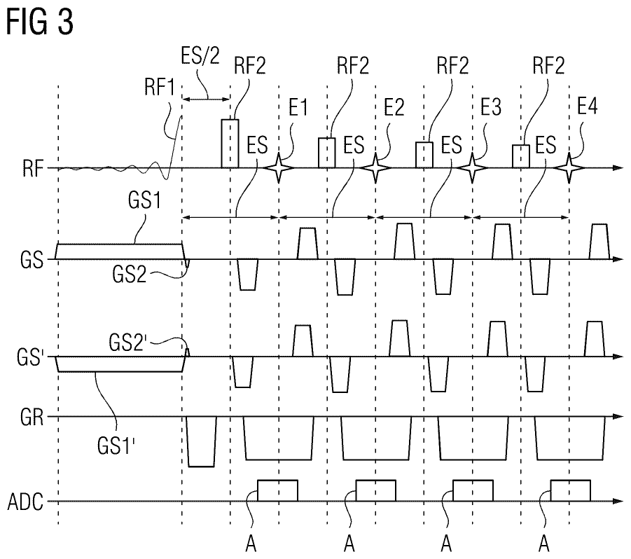

FIG. 3 is a possible schematic sequence diagram which can be used for acquiring measurement data MD, wherein RF pulses to be applied are shown in the top line RF, gradients to be switched in the slice-encoding direction are shown in the second line GS, alternative gradients to be switched in the slice-encoding direction if necessary in a further acquisition of measurement data are shown in the third line GS′, gradients to be switched in the readout direction are shown in the fourth line GR, and acquisition time windows A within which raw data is acquired as measurement data are shown in their succession in time in the bottom line ADC.

In the example of FIG. 3, an RF half-pulse, which corresponds, for example, to a, in particular, first, half of a symmetric RF excitation pulse, is applied as an asymmetric RF excitation pulse RF1 such that the isodelay time of the RF half-pulse RF1 lies at the end of the RF half-pulse RF1. This isodelay time is marked by a dashed vertical line shown in FIG. 3 at the end of the RF half-pulse RF1, which is applied as an RF excitation pulse RF1.

Asymmetric RF excitation pulses RF1 whose isodelay point lies closer to the end of the asymmetric RF excitation pulse than to its beginning can therefore be, for example, what are termed RF half-pulses, as e.g., have already been described in the context of an imaging procedure with ultra-short echo time (UTE) in the article by Pauly et al. titled “Slice-Selective Excitation for Very Short T2 Species”, Proc. SMRM, p. 28, 1989.

By UTE imaging is understood imaging of substances whose T2* decay time is so short that in conventional imaging the transverse magnetization after the echo time TE, i.e., at the echo time point, has already largely decayed. The echo time TE is in this case the time interval between the isodelay time of the RF excitation pulse used and the time point at which the accumulated phase of the gradients in the readout direction is zero, and accordingly a gradient echo is formed.

As is described in the cited article by Pauly et al., RF half-pulses are used there as RF excitation pulses to shorten the echo time further, wherein the RF (half) excitation pulse in the 2D UTE-GRE sequence shown there corresponds to a first half of a conventional symmetric RF pulse and each k-space point is acquired twice with the 2D UTE-GRE sequence, wherein the direction of the slice selection gradient is inverted between the first and second acquisition of a k-space point. The doubly acquired raw data points are complexly added. Provided no irregularities are present (e.g., field inhomogeneities, eddy currents, or motion), the resulting signal is the same as a signal generated by means of a conventional excitation (with full RF pulse). In the formalism of the excitation k-space (also called RF k-space), the trajectory for positive slice selection gradients begins at the k-space minimum and ends at the k-space origin, wherein a relative k-space weighting (RF pulse amplitude) corresponds to a centrally truncated conventional RF pulse. The trajectory of the second excitation (with negative slice selection gradient) starts at the k-space maximum and ends at the k-space origin with corresponding k-space weighting.

The isodelay point of each such RF half-pulse is at the end of the RF half-pulse. As a result, the echo time is shortened by half the duration of the conventional (full) RF pulse. Furthermore, it is customary in UTE imaging to play out the RF half-pulse until the end of the falling edge of the slice selection gradient so that the end of the RF half-pulse coincides with the end of the slice selection gradient. This enables slice rephasing gradients to be dispensed with completely. The amplitude of the RF half-pulses, which are played out during the falling ramp, is reduced accordingly (as with VERSE).

In contrast to a UTE imaging, in the sequence shown in FIG. 3, after the application of the asymmetric RF excitation pulse RF1, a sequence of at least two RF refocusing pulses RF2, with a first time interval ES from one another in each case, is applied in order to generate spin echo signals such that, as is typical with TSE sequences, a spin echo signal E1, E2, E3, E4 is formed after each RF refocusing pulse. The time interval ES between the RF refocusing pulses RF2 corresponds to the echo spacing ES between the spin echo signals E1, E2, E3, E4 of the generated train of spin echo signals E1, E2, E3, E4.

For spatial encoding of the generated spin echo signals E1, E2, E3, E4, gradients, such as, for example, phase encoding gradients, are switched, e.g., in the slice selection direction GS, (in a per se known manner) before and after each RF refocusing pulse RF2, and/or prephasing gradients are switched in the readout direction between the RF excitation pulse RF1 and the first RF refocusing pulse RF2.

The generated spin echo signals E1, E2, E3, E4 are measured in a readout window A in each case, with switching of gradients for spatial encoding in the readout direction GR, after each applied RF refocusing pulse RF2, and stored as measurement data in the k-space in accordance with the respective spatial encoding, from which image data can be reconstructed.

In this case, a time interval ES/2 between the isodelay time of the asymmetric RF excitation pulse RF1 and the temporal center of the first RF refocusing pulse RF2 following the RF excitation pulse RF1 is equal to half the first time interval ES.

The first CPMG condition is thus met.

During the application of the asymmetric RF excitation pulse RF1, a slice selection gradient GS1 can be switched in the slice selection direction GS in order to allow the asymmetric RF excitation pulse RF1 to act only selectively in a desired slice.

If no slice selection gradient GS1 is switched, the asymmetric RF excitation pulse does not act in a spatially selective manner. The use of an asymmetric RF excitation pulse RF1 proposed here also as a non-selective RF excitation pulse instead of a known RF hard pulse mostly used for this purpose has the advantage that the asymmetric RF excitation pulse will usually have a smaller amplitude than a correspondingly acting RF hard pulse, such that an SAR exposure can be reduced. Furthermore, using a proposed asymmetric RF excitation pulse RF1, in particular for RF half-pulses RF1 as asymmetric RF excitation pulses RF1, due to its isodelay time lying closer to the end of the asymmetric RF excitation pulse RF1 than to its beginning, even compared to an RF hard pulse as non-selective excitation pulse, a reduction in a minimum achievable echo spacing ES can be achieved.

If a slice selection gradient GS1 is switched in the slice selection direction GS during the applying of the asymmetric RF excitation pulse RF1, the asymmetric RF excitation pulse RF1 can be designed in such a way that it generates a linear phase response of the magnetization excited by the RF excitation pulse RF1 in the examination subject U along the direction of the slice selection gradient. The asymmetric RF excitation pulse can therefore be, in particular, a linear-phase pulse.

In this case, following the slice selection gradient GS1, a slice rephasing gradient GS2 can be switched, in particular immediately, which compensates for the generated phase response, also referred to as phase dispersion. Since a phase response is generated only from the isodelay time of the asymmetric RF excitation pulse and up to the end of the slice selection gradient GS1, the phase response in the example shown in FIG. 3 is generated only in the region of the falling edge of the slice selection gradient GS1, such that a compensating slice rephasing gradient GS2 is small.

It is also conceivable to apply the slice selection gradient GS1 in such a way that it ends already with the isodelay time, in this case, in the example of FIG. 3, therefore the end, of the asymmetric RF excitation pulse RF1. In this way, no phase response is generated by the asymmetric RF excitation pulse RF1, such that a slice rephasing gradient GS2 can be dispensed with. However, an approach of this kind leads to no further shortening of the echo spacing ES, though it may increase a sensitivity of the sequence toward off-resonance effects (due to B0 inhomogeneities) as well as system imperfections of the magnetic resonance system, such as gradient delay times.

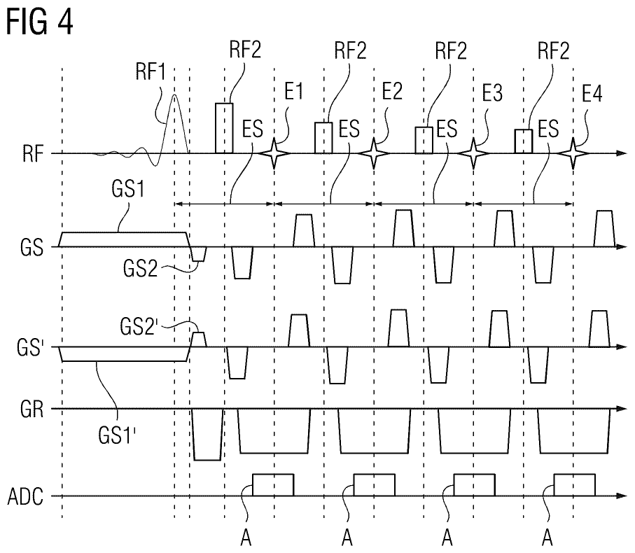

FIG. 4 is a further example of a possible schematic sequence diagram that can be used for the acquisition of measurement data MD, wherein, as in FIG. 3, there are shown, in their temporal succession, applied RF pulses in the top line RF, gradients to be switched in the slice-encoding direction in the second line GS, possibly alternative gradients to be switched in the slice-encoding direction in a further acquisition of measurement data in the third line GS′, gradients to be switched in the readout direction in the fourth line GR, and acquisition time windows A, within which raw data is acquired as measurement data, in the bottom line ADC.

In the example of FIG. 4, in contrast to the example of FIG. 3, an asymmetric RF excitation pulse RF1 corresponding to a truncated (cropped) symmetric RF excitation pulse is applied as an asymmetric RF excitation pulse RF1, wherein a length in time of the asymmetric RF excitation pulse RF1 is greater than half the length in time of the non-truncated symmetric RF excitation pulse on which the asymmetric RF excitation pulse RF1 is based. For this purpose, a symmetric RF excitation pulse can, for example, be truncated in its second half so that the isodelay time of the thus resulting asymmetric RF excitation pulse RF1 lies closer to the end of the asymmetric RF excitation pulse RF1 than to its beginning.

More than half of a conventional symmetric RF excitation pulse is therefore played out as the asymmetric RF excitation pulse RF1. In the example shown in FIG. 4, roughly the first half and the second half up to the first zero point of a SINC pulse with time-bandwidth product 16 are played out.

A symmetric SINC pulse with time-bandwidth product 16 has Nₗ=8 zero points in the first and Nᵣ=8 zero points in the second half. The width of the central lobe is twice as large as the respective width b of the side lobes. The duration of the pulse is T=b×(Nₗ+Nᵣ).

If such a SINC pulse is cut off, for example, at its first right zero point, i.e., the first zero point after the central peak, and the thus truncated SINC pulse is inserted as an asymmetric RF excitation pulse in a CPMG-TSE sequence, then the echo spacing saving compared to the use of the symmetric pulse amounts to at least:

$$Δ ES = 2 \times ( {N}_{r} - 1 ) \times b$$

The factor 2 stems from the fact that the spacing between isodelay time of the thus obtained RF excitation pulse RF1 and the center of the first RF refocusing pulse RF2 amounts to

$$\frac{ES 2}{2} .$$

Further savings for the minimum echo spacing ES are possible since the moment of the slice rephasing gradient GS2, GS2′ is also reduced.

It can be advantageous to construct an asymmetric RF excitation pulse RF1 as an asymmetric variant of an existing RF excitation pulse in order e.g., to obtain the same or a very similar slice profile.

An asymmetric RF excitation pulse RF1 can also be determined, for example, on the basis of a Shinnar-Le Roux (SLR) pulse. An SLR pulse is an RF pulse that has been designed by means of the Shinnar-Le Roux (SLR) algorithm. The SLR algorithm permits the RF samples of an RF pulse to be calculated as an SLR pulse from specifications such as RF bandwidth, pulse duration, flip angle, and the parameterized slice profile. The calculated RF samples (normalized amplitude and phase) of the SLR pulse can for example be stored in a file for a planning of a magnetic resonance measurement. The RF samples can be read out from the file in order to construct an asymmetric RF excitation pulse RF1 from these RF samples of the SLR pulse provided as a basis. If a provided SLR pulse is not exactly symmetrical (which will mostly be the case), a virtual synthetic symmetric pulse can be constructed initially by an averaging of read RF samples. In this process, two RF samples in each case can be averaged, for example, in the following way:

$${\tilde{s}}_{\frac{N}{2} - j} = {\tilde{s}}_{\frac{N}{2} + j - 1} = \frac{{s}_{\frac{N}{2} - j} + {s}_{\frac{N}{2} + j - 1}}{2} , for j = 1 , … , \frac{N}{2} .$$

Here, \tilde{s}ᵢ are the complex RF samples of the virtual pulse, sᵢ are the complex RF samples of the provided SLR pulse, N is the total number of RF samples, which is mostly even. The RF samples are indexed here from 0 to N−1.

The asymmetric RF excitation pulse RF1 can then be constructed from the virtual symmetric pulse. If the dwell time (time between two RF samples) is different from the constructed asymmetric RF excitation pulse RF1 and different from the dwell time of the provided SLR pulse, it is possible to interpolate between the RF samples. Otherwise, the asymmetric RF excitation pulse can be obtained from the virtual pulse by retaining only some of the RF samples of the symmetric virtual pulse.

If an example SLR pulse has approximately N=1024 RF samples, a duration of 10240 μs, and a time-bandwidth product of 22, the central lobe of the SLR pulse extends over roughly 88 RF samples.

For a specific symmetric RF excitation pulse as the starting point for an asymmetric RF excitation pulse RF1, a better slice profile is usually achieved using an RF excitation pulse RF1 that is more than half of a conventional symmetric RF excitation pulse than with an RF half-pulse (of the same symmetric RF excitation pulse as starting point) as an asymmetric RF excitation pulse RF1. The cause for this is presumably an increased robustness of the longer asymmetric RF excitation pulse RF1 toward system imperfections.

The asymmetric RF excitation pulse RF1 can generally be derived from a symmetric RF excitation pulse by suppressing (i.e., not playing out), e.g., at least a part of the second half of the symmetric RF excitation pulse.

Also in the example shown in FIG. 4, for spatial encoding of the generated spin echo signals E1, E2, E3, E4, gradients, such as for example phase encoding gradients, are switched (in a per se known manner), e.g., in the slice selection direction GS, before and after each RF refocusing pulse RF2, and/or prephasing gradients are switched in the readout direction between the RF excitation pulse RF1 and the first RF refocusing pulse RF2.

The generated spin echo signals E1, E2, E3, E4 are measured in a readout window A in each case, while gradients for spatial encoding are switched in the readout direction GR, after each applied RF refocusing pulse RF2 and stored as measurement data in the k-space according to the respective spatial encoding, from which image data can be reconstructed.

In this case, a time interval ES/2 between the isodelay time of the asymmetric RF excitation pulse RF1 and the temporal center of the first RF refocusing pulse RF2 following the RF excitation pulse RF1 is again equal to half the first time interval ES. Accordingly, the first CPMG condition is also met here.

While the asymmetric RF excitation pulse RF1 is applied, a slice selection gradient GS1 can be switched in the slice selection direction GS in order to allow the asymmetric RF excitation pulse RF1 to act only selectively in a desired slice.

If no slice selection gradient GS1 is switched, the asymmetric RF excitation pulse does not act in a spatially selective manner. The use of an asymmetric RF excitation pulse RF1 proposed here also as a non-selective RF excitation pulse instead of a known RF hard pulse, mostly used for this, also has the advantage here that the asymmetric RF excitation pulse will usually have a smaller amplitude than a correspondingly acting RF hard pulse, such that an SAR exposure can be reduced. In addition, using a proposed asymmetric RF excitation pulse RF1, also for asymmetric RF excitation pulses RF1 which are longer than an RF half-pulse, due to its isodelay time lying closer to the end of the asymmetric RF excitation pulse RF1 than to its beginning compared to an RF hard pulse as a non-selective excitation pulse, it is possible to achieve a reduction in a minimum achievable echo spacing ES.

If a slice selection gradient GS1 is switched in the slice selection direction GS while the asymmetric RF excitation pulse RF1 is being applied, the asymmetric RF excitation pulse RF1 can be designed such that it generates a linear phase response of the magnetization excited by the RF excitation pulse RF1 in the examination subject U along the direction of the slice selection gradient. The asymmetric RF excitation pulse can therefore be, in particular, a linear-phase pulse.

In this case, a slice rephasing gradient GS2, which compensates for the generated phase response, can be switched, in particular immediately, following the slice selection gradient GS1. A phase response is generated in the time period from the isodelay time of the asymmetric RF excitation pulse RF1 up to the end of the slice selection gradient GS1. In the example of FIG. 4, the slice selection gradient GS1 ends with the RF excitation pulse RF1 such that a phase response is generated from the isodelay time of the asymmetric RF excitation pulse RF1 up to the end of the asymmetric RF excitation pulse RF1. The slice rephasing gradient GS2 to be switched for the compensation is therefore greater than the slice rephasing gradient GS2 from the example of FIG. 3, though it is still small, such that it has no negative effect on an achievable echo spacing ES.

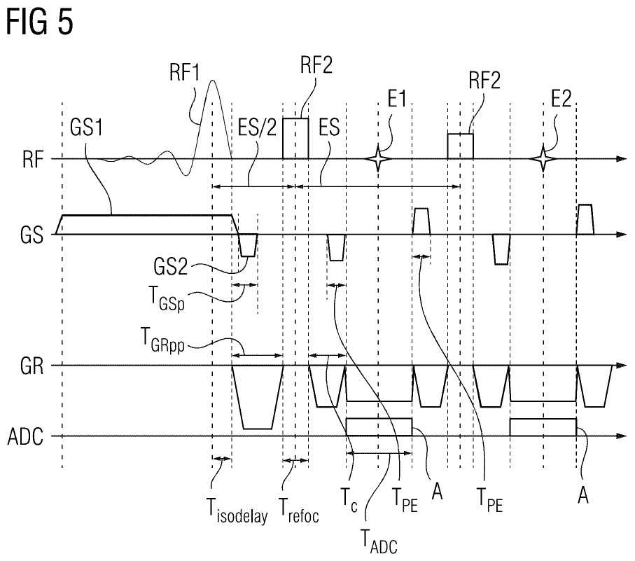

FIG. 5 is a further example of a possible schematic sequence diagram which can be used for the acquisition of measurement data MD, wherein, as in FIGS. 3 and 4, RF pulses to be applied are shown in the line RF, gradients to be switched in the slice encoding direction are shown in the line GS, gradients to be switched in the readout direction are shown in the line GR, and acquisition time windows A within which raw data is acquired as measurement data are shown in their temporal succession in the line ADC.

In the example of FIG. 5, an asymmetric RF excitation pulse RF1 is applied, the isodelay time of which is closer to the end of the RF excitation pulses RF1 than to its beginning, though it does not exactly coincide with the end of the RF excitation pulse RF1. In order to determine an asymmetric RF excitation pulse RF1 of the example of FIG. 5, the same procedure can be followed as in the example of FIG. 4. The RF excitation pulse RF1 can be, in particular, a linear-phase pulse in this example, also.

In contrast to FIG. 4, FIG. 5 shows an example in which a switched slice selection gradient GS1 is switched in such a way that its plateau ends with the applied RF excitation pulse RF1 such that the falling edge of the slice selection gradient GS1 begins only at or after the end of the RF excitation pulse RF1. If no slice selection gradient GS1 were to be switched, what was stated above with reference to FIG. 4 applies analogously. The fact that the falling edge of the slice selection gradient GS1 begins only after the end of the asymmetric RF excitation pulse RF1 causes a reduced sensitivity of the sequence toward off-resonance effects and system imperfections of the magnetic resonance system.

In FIG. 5, analogously to the examples of FIGS. 3 and 4, inverted slice selection gradients GS1′ can be used for multiple acquisitions of measurement data, though these are not shown in FIG. 5 for clarity of illustration reasons.

If a slice selection gradient GS1, as shown in FIG. 5, is switched, the slice selection gradient GS1 can again be followed, in particular immediately, by a slice rephasing gradient GS2, which compensates for a generated phase response. A phase response is generated in the period of time from the isodelay time of the asymmetric RF excitation pulse RF1 up to the end of the slice selection gradient GS1. In the example of FIG. 5, the slice selection gradient GS1 ends only after the end of the asymmetric RF excitation pulse RF1. The slice rephasing gradient GS2 to be switched for compensation purposes in the example of FIG. 5 is therefore greater than the slice rephasing gradient GS2 from the example of FIG. 4, yet is still small, such that it has no negative impact on an achievable echo spacing ES because these are already limited by the CPMG conditions due to the RF refocusing pulses to be applied and the gradients to be switched after the RF excitation pulse.

This limiting of the echo spacing ES is illustrated generally in FIG. 5 (for all examples in FIGS. 3 to 5). A slice rephasing gradient GS2 to be switched has no effect on an achievable minimum echo time ES as long as a duration TGRpp of a prephasing gradient to be switched between the asymmetric RF excitation pulse RF1 and the first RF refocusing pulse RF2 in the readout direction GR is greater than a time period TGSp which elapses after the end of the asymmetric RF excitation pulse RF1 up to the end of the switched slice rephasing gradient GS2.

It follows from condition 1 namely, for example, that the minimum echo spacing ES of a CPMG-TSE sequence is limited downward by the duration Trefoc of the applied RF refocusing pulses RF2 and the gradients to be switched between these:

$$ES \geq ( {T}_{refoc} + {T}_{ADC} + max ( 2 \times {T}_{PE} , 2 \times {T}_{c} ) ) \qquad ( 1 )$$

In this case T_{refoc} is the duration of an RF refocusing gradient RF2, T_{ADC} is the duration of the readout window A, T_{PE} is the duration of a phase encoding or phase refocusing gradient, which are switched, e.g., for spatial encoding before and after the generated spin echo signals E1, E2, E3, E4, and T_{c} is the duration of a possibly switched crusher gradient.

On the other hand, it also follows from condition 1 that the minimum echo spacing ES is limited downward by the isodelay time of the RF excitation pulse RF1, the duration of the first RF refocusing pulse RF2 and the duration of the gradients to be switched between excitation and first RF refocusing pulse RF2:

$$ES \geq 2 \times ( {T}_{isodelay} + \frac{{T}_{refoc}}{2} + max ( {T}_{GRpp} , {T}_{GSp} ) ) \qquad ( 2 )$$

In this case T_{isodelay} is the time between the isodelay time of the RF excitation pulse RF1 and the end of the RF excitation pulse RF1, T_{refoc} is again the duration of an RF refocusing pulse RF2, T_{GRpp} the duration of a prephasing gradient to be switched in the readout direction, and T_{GSp} is composed of a duration of the slice rephasing gradient GS2 and a duration of the falling edge of the slice selection gradient GS1.

If a conventional symmetric selective RF excitation pulse of a SPACE sequence has for example a duration of 10240 μs and consequently an isodelay time of T_{isodelay}=5120 μs, it follows from formula 2 that no CPMG sequence having an echo spacing ES in the order of 4 ms can be constructed with this isodelay time. The above-described SPACE techniques with extended first echo spacing, though allowing shorter second echo spacings, nonetheless have the described disadvantages.

Furthermore, the minimum echo spacing ES is also limited downward by formula 1. It follows from this, other than with an above-described GRE sequence of the UTE imaging in which the RF half-pulses whose isodelay time coincides with the end of the RF half-pulse are used to minimize the echo time, that a shortening of the isodelay time T_{isodelay} of the RF excitation pulses is not necessarily followed also by a shortening of the echo spacing ES. In the TSE sequence technique, an asymmetric RF excitation pulse described here with a short but (in contrast to an RF half-pulse) non-zero isodelay time T_{isodelay} can be advantageous without an extension of the minimum echo spacing ES necessarily following from the non-zero isodelay time T_{isodelay}. Compared to an RF half-pulse, asymmetric RF excitation pulses RF1 having a short but non-zero isodelay time T_{isodelay} have the advantage that better slice profiles are achieved since they have a greater robustness against system imperfections.

The proposed asymmetric RF excitation pulses can therefore be used in any 2D or 3D TSE sequence, wherein the cited advantages are produced in particular for TSE sequences in which the timing conditions described by the CPMG conditions between RF excitation pulse and first RF refocusing pulse limit an achievable echo spacing downward.

Measurement data for at least one spatial encoding can also be acquired multiple times, at least twice, after identical asymmetric RF excitation pulses and following RF refocusing pulses have been applied, wherein the polarity of the slice selection gradient switched by means of the respective asymmetric RF excitation pulse is different for different acquisitions such that further measurement data (MD′) is acquired by means of a further execution of the sequence (block 201′) for at least one spatial encoding.

In this case all the measurement data, i.e., measurement data for each spatial encoding, can be acquired multiple times, at least twice, or it is also possible to acquire only a portion of the measurement data multiple times, e.g., with only for a specific, for example a central, spatial encoding. Dispensing with a multiple acquisition of all the measurement data leads to a saving in the total amount of measurement time to be expended for all the acquisitions.

With a multiple acquisition of measurement data of a spatial encoding in which slice selection gradients switched for different acquisitions are different from one another, it is possible, as illustrated in FIGS. 3 and 4, for example to apply the gradients to be switched in the line GS for at least one acquisition in the slice selection direction, and to apply the gradients to be switched in the line GS' for at least one further acquisition in the slice selection direction. The gradients to be switched for a multiple acquisition of measurement data of a spatial encoding for different acquisitions are therefore different from one another, in this case, for example, only in the sign of the switched slice selection gradient GS1, GS1′. If a slice rephasing gradient GS2, GS2′ is switched, then its sign is also inverted for at least one further acquisition, according to the slice selection gradient GS1, GS1′.

Furthermore, as well as the cited gradients in the slice selection direction, a phase of the applied RF refocusing pulse RF2 can also be changed for a multiple acquisition of measurement data of a spatial encoding for different acquisitions such that it is different for different acquisitions of measurement data of a spatial encoding by 180°. Such a procedure is known as “phase cycling” and can be used for eliminating so-called FID artifacts (FID: Free Induction Decay).

FID artifacts can constitute a problem, particularly with SPACE, or single-slab 3D FSE sequences. FID artifacts are produced when longitudinal magnetization which has resulted, e.g., due to T1 decay during an echo train is excited by an RF refocusing pulse having a flip angle <180° into the transverse plane. Relatively long echo trains of these sequences are a first reason why FID artifacts can be particularly problematic in the single-slab 3D FSE sequences. A further problem is the significant deviation of the flip angles from 180° and consequently the relatively large proportion of the longitudinal magnetization that is excited instead of inverted by the RF refocusing pulse. A detailed discussion of FID problems can be found in the already cited article by Mugler III. Especially when a multiple acquisition of measurement data of a spatial encoding is to be performed already even without phase cycling, and since RF excitation pulses are not involved in the generation of FID artifacts, a phase cycling can simply be combined with the method described here without involving a further extension of the acquisition time.

Thus, for example, an echo train can be acquired a second time with inverted slice selection gradient GS1′ and with phase of the RF refocusing pulses incremented by 180° in each case relative to the first execution of the echo train in order to acquire the measurement data of a spatial encoding multiple times (in this case, e.g., twice) and using a phase cycling method to avoid FID artifacts. At the same time, a repetition of an acquisition of measurement data with inverted slice selection gradient GS1′ and/or incremented phase can be performed immediately after the first execution (i.e., in the time interval of the repetition time TR) in order to make the method as a whole robust against patient movements or other time-related fluctuations during the acquisitions.

For example, for a multiple, e.g., double, acquisition of measurement data using the same spatial encoding, each echo train E1, E2, E3, E4 can be acquired following an asymmetric RF excitation pulse RF1 once by means of slice selection gradients GS1 and a second time by means of inverted slice selection gradients GS1′.

Especially for RF half-pulses RF1 as asymmetric RF excitation pulses RF1, such a multiple acquisition of at least some measurement data of the same spatial encoding is recommended in order, as described in the cited article by Pauly et al., to be able to achieve an excitation profile corresponding to or at least approximating a conventional symmetric excitation. For truncated symmetric RF excitation pulses as asymmetric RF excitation pulses RF1, a multiple acquisition of measurement data using the same spatial encoding can be dispensed with if an at least theoretical degradation of the achieved slice profile is accepted.

If measurement data MD and MD′ were acquired a number of times for at least one spatial encoding, then this data can be complexly added (block 203) in order to obtain added measurement data aMD from which image data (BD) can be reconstructed (block 205). By means of such a complex addition or on the basis of such a complex addition, measurement data corresponding to measurement data acquired using a symmetric excitation can be easily determined from the multiply acquired measurement data.

For multiple acquisitions of measurement data using the same spatial encoding, which can be specified for example already in the loaded parameters P, the respective RF excitation pulses RF1 of the multiple acquisitions performed in this process of measurement data of the same spatial encoding can be subjected to a density compensation method (block 202) which adjusts the amplitude response of the RF excitation pulse according to the multiple acquisitions in such a way that an adjustment of amplitudes of the RF excitation pulse RF1 corresponding to RF k-space points which are played out in multiple repetitions of the multiple acquisitions compared to amplitudes of the RF excitation pulse RF1 corresponding to RF k-space points which are played out in only one of the multiple acquisitions is performed which compensates for the multiple acquisition.

For example, in this context, depending on whether, e.g., an acquisition of a specific echo train is repeated in order to acquire measurement data of the same spatial encoding several times or not, a density compensation is performed in the RF k-space such that the amplitude of RF samples of the RF excitation pulse RF1 corresponding to RF k-space points which are played out in, for example, m repetitions can be weighted with a factor of 1/m compared to RF samples of the RF excitation pulse RF1 corresponding to k-space points which are played out only in one of the repetitions of the acquisition of the measurement data of the same spatial encoding. Analogously, a density compensation can be performed in the RF k-space such that the amplitude of RF samples of the RF excitation pulse RF1 corresponding to RF k-space points which are played out in only one repetition are weighted with a factor of m compared to RF samples of the RF excitation pulse RF1 corresponding to k-space points which are played out in m repetitions of the acquisition of the measurement data of the same spatial encoding. These are just two examples for density compensation. Further normalizations for compensating for multiple acquisitions are conceivable.

If the asymmetric RF excitation pulse RF1 is derived from a symmetric RF excitation pulse, for example by means of a truncation in which, e.g., at least a part of the second half of the symmetric RF excitation pulse is suppressed (i.e., not played out), the amplitude of the played-out RF samples can be adjusted such that the amplitude integral is unchanged.

An amplitude response of the asymmetric RF excitation pulse RF1 can in this case be adjusted compared to the amplitude response of the original symmetric RF excitation pulse such that an integral over the combined asymmetric RF excitation pulse amplitudes of the RF excitation pulses RF1 and associated slice selection gradients GS1, GS1′ used accordingly in the RF k-space in the multiple acquisition corresponds to the integral over the amplitude of the original symmetric RF excitation pulse.

For the asymmetric RF excitation pulse cited above by way of example, which was constructed on the basis of the cited SLR pulse, the normalized RF samples ŝᵢ of an asymmetric RF excitation pulse RF1 which results from the symmetric virtual pulse by truncation after the first zero point to the right of the peak receive, e.g., the following rule:

$${\hat{s}}_{i} = \{ \begin{matrix}2 \times {\tilde{s}}_{i} \\ {\tilde{s}}_{i}\end{matrix} f \ddot{u} r \begin{matrix}i = 0 , … , 467 \\ i = 468 , … , 555\end{matrix}$$

The factor 2 with which the first 468 samples are weighted corresponds here to an example density compensation in the RF k-space. Such an asymmetric RF excitation pulse RF1 would have a duration of 5560 μs. A TE contribution (time between isodelay point and end of the RF pulse) would in this case therefore be only 440 μs compared with 5120 μs (half the duration of the underlying SLR pulse, 10240 μs/2) of the original SLR pulse.

The zero points of the amplitude of the RF excitation pulse do not change hereby as a result of the density compensation.

Accordingly, the RF excitation pulses RF1 used may, however, be different for different measurement data, depending on whether the measurement data is acquired multiple times (and a density compensation has been performed) or not (and no density compensation has been performed).

For excitation volumes having an orientation perpendicular to a read-out slice, in which therefore a cross-section through the excitation volume is imaged, comparisons of slice profiles obtained by means of a conventional symmetric RF excitation pulse (isodelay time T_{isodelay}=5120 μs), by means of which two identical acquisitions of all the measurement data have been acquired and averaged, as reference slice profile and of asymmetric RF excitation pulses proposed here as RF half-pulses (isodelay time T_{isodelay}=0 μs) on the one hand and as asymmetric RF excitation pulses having an isodelay time T_{isodelay} greater than zero (isodelay time T_{isodelay}=440 μs) on the other, which have been derived from the symmetric RF excitation pulse, have yielded the following:
A) A slice profile which was achieved in just one acquisition of measurement data using RF half-pulses as asymmetric RF excitation pulses differs significantly from a slice profile achieved using the symmetric RF excitation pulse, wherein even signal from outside of the defined excitation volume contributed.
B) A slice profile which was achieved with RF half-pulses and a double acquisition of all the measurement data, wherein during the second acquisition the direction of the respective slice selection gradient was inverted compared to the first acquisition, and the acquired signals of each acquired k-space point from the first and the second acquisition were complexly added, is significantly improved compared with the just one-time acquisition of the measurement data with RF half-pulses, although unexpected ringing artifacts were evident at the boundaries of the excitation volume.
C) A slice profile which was achieved in just one acquisition of measurement data with asymmetric RF excitation pulses having an isodelay time T_{isodelay} greater than zero which corresponds to the symmetric RF excitation pulse truncated at the first zero point to the right is, compared to that with a simple acquisition of the measurement data with RF half-pulses, significantly closer to the reference slice which was achieved for the acquisitions with the symmetric RF excitation pulse such that, by retaining the complete central lobe of the RF excitation pulse also in the asymmetric RF excitation pulse, even with simple acquisition of all the measurement data of the spatially encoded k-space points, a slice profile was already achieved which comes close to the quality of the reference slice profile.
D) A slice profile which was achieved with the same asymmetric RF excitation pulses as in the case of the simple acquisition of the measurement data, but now with a double acquisition of all the measurement data, wherein in the second acquisition the direction of the respective slice selection gradient was inverted compared to the first acquisition, and the acquired signals of each acquired k-space point from the first and the second acquisition were complexly added, is even closer to the reference slice profile than in the case of the simple acquisition of the measurement data, wherein, compared to the reference slice profile, however, a slight blurring of the edges as well as an edge ringing were evident.
E) A slice profile which was achieved with density-compensated asymmetric RF excitation pulses and a double acquisition of all the measurement data, wherein in the second acquisition the direction of the respective slice selection gradient was inverted compared to the first acquisition, and the acquired signals of each acquired k-space point from the first and the second acquisition were complexly added, is scarcely to be distinguished from the reference slice profile.

As a result of the density compensation, the asymmetric RF excitation pulses of comparisons D) and E) are not identical, but (as described above and further below) RF samples of the central lobe of the density-compensated RF excitation pulses are weighted with a factor 0.5 compared to RF samples of the side lobes. In a normalized envelope, the side lobes of the density-compensated RF excitation pulses (comparison E) are thus raised by a factor 2 compared to the side lobes of the corresponding non-density-compensated RF excitation pulse (comparison D).

Accordingly, a slice profile of the quality of conventional TSE imaging can also be achieved in spatially selective TSE imaging with symmetric RF excitation pulses, but lengthened first echo spacing with the herein-described asymmetric RF excitation pulses, wherein precisely this lengthening of the first echo spacing and consequently the disadvantages associated with this are avoided.

Compared to a conventional SPACE sequence as has been used for the acquisitions of the reference slice profile, an acquisition according to comparison E) with density-compensated asymmetric RF excitation pulses having an isodelay time greater than zero and double acquisition of the measurement data with inverted slice selection gradient still has the advantage that, given otherwise identical sequence parameters, it is significantly less sensitive to B1 inhomogeneities and the fat/water contrast is more similar to a 2D TSE sequence such that fat signal appears brighter.

To sum up, the following advantages can be achieved through the use of the asymmetric RF excitation pulses in TSE sequences proposed here:

For example, a (spatially) selective single-slab 3D TSE sequence is made possible, which achieves an echo spacing corresponding to a (short) echo spacing of a (spatially) non-selective single-slab 3D TSE sequence or even a shorter echo spacing, and at the same time, the CPMG conditions are met such that a lengthening of the first echo spacing is not necessary. Such an omission of an extension of the first echo spacing significantly reduces the B1 sensitivity of the obtained TSE sequence. Furthermore, a reduction in fat signal induced by J coupling, which produces a change in fat/water contrast, is likewise avoided by the omission of an extension of the first echo spacing such that a fat/water contrast corresponds to a fat/water contrast of a 2D TSE sequence, which continues to represent the clinical standard. This can be an advantage (e.g., on account of the higher bone signal), in particular in MSK imaging.

If measurement data is acquired more than once, e.g., twice, with inverted slice selection gradients, a slice profile achieved using RF half-pulses as asymmetric RF excitation pulses and combination of the measurement data is theoretically identical with a slice profile of a complete symmetric RF excitation pulse obtained by mirroring the RF half-pulse. By using asymmetric RF excitation pulses with an isodelay time greater than zero, an achievable slice profile can be significantly improved compared with RF half-pulses without this necessarily leading to a lengthening of the echo spacing. This applies both with and without repetition of measurement data acquisitions (e.g., by repeated acquisition of echo trains).

TSE sequences having a VERSE pulse as RF excitation pulse are more sensitive to inhomogeneities in the basic magnetic field B0 compared to TSE sequences having the proposed asymmetric RF excitation pulses, which is a disadvantage in particular when fat is not to be or cannot be suppressed in the image. The asymmetric RF excitation pulses proposed here do not have this disadvantage. Furthermore, a VERSE pulse is generally longer (e.g., 960 μs, and hence isodelay time 480 μs) than a non-selective RF excitation pulse (e.g., 600 μs). In addition, a slice rephasing gradient is necessary when VERSE pulses are used. For the two last-mentioned reasons, given otherwise identical parameters, it is usually necessary to lengthen an echo spacing of the TSE sequence using VERSE pulses compared to the non-selective variant. The lengthening of the echo spacing reduces efficiency and increases T2 blurring.

The asymmetric RF excitation pulse used for the above-described comparisons C), D) and E) has a duration of 5120 μs before the isodelay time point and 440 μs thereafter. The isodelay time (and consequently a possible contribution to an achievable minimum echo spacing) accordingly amounts to 440 μs and is therefore shorter than that of the VERSE pulse (480 μs). In this case a moment of a slice rephasing gradient to be switched for an asymmetric RF excitation pulse is significantly less than for a VERSE pulse, thereby enabling the slice rephasing gradient to be chosen shorter. A slice selection gradient that is switched during the applying of a VERSE pulse as RF excitation pulse must vary in its strength. For asymmetric RF excitation pulses proposed here, a constant slice selection gradient can be used. This increases the robustness toward system imperfections, in particular gradient delay times.

Compared to selective single-slab 3D TSE sequences using adiabatic RF pulses for the excitation as described in the cited article by Park et al., TSE sequences using proposed asymmetric RF excitation pulses are not limited to one T2 contrast but also permit contrasts that require shorter echo times. In addition, a B1 sensitivity is reduced for proposed asymmetric RF excitation pulses without the need to use SAR-intensive adiabatic RF pulses. As already mentioned, the TSE sequence using adiabatic RF pulses described in the article by Park et al. also suffers under an attenuated fat signal induced by J coupling due to the lengthened first echo spacing in contrast to the proposed TSE sequences using asymmetric RF excitation pulses.

Furthermore, the proposed asymmetric RF excitation pulses can also be used for example for TSE sequences with selective RF excitation pulses and RF refocusing pulses in order (e.g., by choosing a correspondingly large time-bandwidth product of the asymmetric RF excitation pulse used) to improve a slice profile of the excitation, wherein as a result a minimum achievable echo spacing is not extended, power limits of a power amplifier for the RF pulses can continue to be observed and an applied SAR is not, or at least not significantly, increased. Furthermore, in this process (significant) deviations of the amplitudes during the applying of RF excitation pulses on the one hand and RF refocusing pulses on the other hand can be dispensed with, which would increase an off-resonance (B0) sensitivity of the sequence. If measurement data of a spatial encoding is to be acquired a number of times in this case, the slice selection gradients for different acquisitions are inverted not only during the RF excitation pulses but in this case also during the RF refocusing pulses.

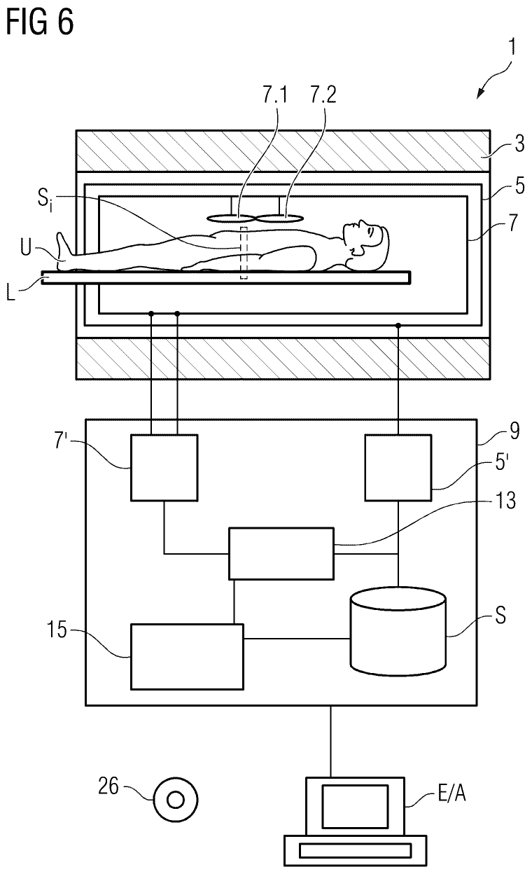

FIG. 6 shows a schematic view of a magnetic resonance system 1 according to the disclosure. This comprises a magnet unit 3 for generating the basic magnetic field, a gradient unit 5 for generating the gradient fields, a radiofrequency unit 7 for transmitting and receiving radiofrequency signals, and a control device 9 designed to perform a method according to the disclosure.

These subunits of the magnetic resonance system 1 are represented only roughly schematically in FIG. 6. The radiofrequency unit 7 may consist of a number of subunits and for example comprise a number of coils. In particular, the radiofrequency unit 7 may comprise a whole-body coil which is permanently integrated in the magnetic resonance system 1 and in turn may comprise for example two antenna elements 7.1 and 7.2. In addition, the radiofrequency unit 7 may comprise one or more different local coils which can be designed either only for transmitting radiofrequency signals or only for receiving the triggered radiofrequency signals or for both, and for their part may comprise a number of antenna elements and associated coil channels.

In order to examine an examination subject U, for example a patient or also a phantom, the subject can be introduced on a couch L into the measurement volume of the magnetic resonance system 1. The slice or slab Sᵢ represents an exemplary target volume of the examination subject from which echo signals can be recorded and acquired as measurement data.

The control device 9 serves for controlling the magnetic resonance system 1 and can in particular control the gradient unit 5 by means of a gradient controller 5′ and the radiofrequency unit 7 by means of a radiofrequency transmit/receive controller 7′. In this case the radiofrequency unit 7 may comprise a number of channels on which signals can be sent or received.

The radiofrequency unit 7 is responsible together with its radiofrequency transmit/receive controller 7′ for generating and broadcasting (transmitting) an alternating radiofrequency field in order to manipulate the spins in a region of the examination subject U that is to be manipulated (for example in slices S that are to be measured). In the process the center frequency of the alternating radiofrequency field, also referred to as the B1 field, is usually adjusted as far as possible so that it lies close to the resonance frequency of the spins that are to be manipulated. Deviations of the center frequency from the resonance frequency are referred to as off-resonance. In order to generate the B1 field, currents controlled in the radiofrequency unit 7 by means of the radiofrequency transmit/receive controller 7′ are applied to the RF coils.

The control device 9 additionally comprises an asymmetry unit 15 for providing asymmetric RF excitation pulses according to the disclosure. Overall, the control device 9 is designed to perform a method according to the disclosure.

A computing unit 13 incorporated in the control device 9 is designed to perform all the computational operations necessary for the required measurements and provisions. Interim results and results required for this or determined in the process can be stored in a memory unit S of the control device 9. The illustrated units are in this case not necessarily to be understood as physically separate units but simply represent a subdivision into notional units, yet which can also be realized, e.g., in fewer physical units or even in just one single physical unit.

Control commands can be directed to the magnetic resonance system, e.g., by a user, and/or results of the control device 9 such as, e.g., image data may be displayed by way of an input/output device E/A of the magnetic resonance system 1.

A herein-described method may also be present in the form of a computer program comprising commands which perform the described method on a control device 9. Similarly, a computer-readable storage medium may be present comprising commands which, when executed by means of a control device 9 of a magnetic resonance system 1, cause said control device to perform the described method.

Independent of the grammatical term usage, individuals with male, female or other gender identities are included within the term.

1. A method for acquiring measurement data of an examination subject using a magnetic resonance system, the method comprising:
applying an asymmetric RF (radio frequency) excitation pulse;
after the asymmetric RF excitation pulse has been applied, applying a sequence of at least two RF refocusing pulses, with a first time interval from one another in each case, in order to generate spin echo signals;
switching gradients for spatial encoding of generated spin echo signals; and
reading out generated spin echo signals after each applied RF refocusing pulse as measurement data in k-space according to the respective spatial encoding, from which image data can be reconstructed,
wherein a time interval between isodelay time of the asymmetric RF excitation pulse and a temporal center of the first RF refocusing pulse following the RF excitation pulse is equal to half the first time interval.

2. The method as claimed in claim 1, wherein a slice selection gradient is switched during application of the asymmetric RF excitation pulse.

3. The method as claimed in claim 2, wherein the asymmetric RF excitation pulse generates a linear phase response of the magnetization excited using the RF excitation pulse in the examination subject along a direction of the slice selection gradient.

4. The method as claimed in claim 3, wherein a slice rephasing gradient is switched following the slice selection gradient.

5. The method as claimed in claim 2, wherein measurement data for at least one spatial encoding is acquired at least twice after applying identical asymmetric RF excitation pulses and following RF refocusing pulses, wherein a polarity of the slice selection gradient switched using the respective asymmetric RF excitation pulse is different for different acquisitions.

6. The method as claimed in claim 5, wherein measurement data acquired multiple times is complexly added and image data is reconstructed from the added measurement data.

7. The method as claimed in claim 5, wherein, for multiple acquisitions of measurement data of the same spatial encoding, the respective RF excitation pulses of the acquisitions of measurement data of the same spatial encoding performed in this process are subjected to a density compensation method which adjusts an amplitude response of the RF excitation pulse according to the multiple acquisitions in such a way that a compensation of amplitudes of the RF excitation pulse corresponding to RF k-space points which are played out in multiple repetitions of the multiple acquisitions is achieved compared to amplitudes of the RF excitation pulse corresponding to RF k-space points which are played out in only one of the multiple acquisitions.

8. The method as claimed in claim 1, wherein the asymmetric RF excitation pulse is an RF half-pulse which corresponds to a half of a symmetric RF excitation pulse such that the isodelay time of the RF half-pulse lies at an end of the RF half-pulse.

9. The method as claimed in claim 7, wherein the asymmetric RF excitation pulse corresponds to a truncated symmetric RF excitation pulse, wherein a length in time of the asymmetric RF excitation pulse is greater than half the length in time of a non-truncated symmetric RF excitation pulse, in that the truncation is performed in a second half of the symmetric RF excitation pulse such that the isodelay time of the asymmetric RF excitation pulse lies closer to an end of the asymmetric RF excitation pulse than to its beginning.

10. The method as claimed in claim 9, wherein measurement data for at least one spatial encoding is acquired at least twice after applying identical asymmetric RF excitation pulses and following RF refocusing pulses, wherein a polarity of the slice selection gradient switched using the respective asymmetric RF excitation pulse is different for different acquisitions, and wherein an amplitude response of the asymmetric RF excitation pulse is adjusted compared to the original symmetric RF excitation pulse such that an integral over a combined asymmetric RF excitation pulse amplitudes of the RF excitation pulses and associated slice selection gradients used accordingly in RF k-space in the multiple acquisition corresponds to the integral over the amplitude of the original symmetric RF excitation pulse.

11. The method as claimed in claim 1, wherein the applied RF refocusing pulses are non-selective.

12. The method as claimed in claim 5, wherein a phase cycling method is applied in a repeated acquisition of measurement data.

13. A magnetic resonance system comprising:
a magnet unit;
a gradient unit;
a radiofrequency unit; and
a control device having a radiofrequency transmit/receive controller and having an asymmetry unit,
wherein the control device is designed to perform a method as claimed in claim 1 on the magnetic resonance system.

14. A non-transitory computer-readable storage medium comprising commands which, when executed by a control device of a magnetic resonance system, cause the control device to perform the method as claimed in claim 1.
